(19) United States
(12) Patent Application Publication
(10) Pub. No.: US 2004/0233639 A1
(43) Pub. Date: Nov. 25, 2004

(54) Removeable heat spreader support mechanism and method of manufacturing thereof

(75) Inventors: Girish Upadhya, San Jose, CA (US); Mark Munch, Los Altos, CA (US); Peng Zhou, Albany, CA (US); Kenneth Goodson, Belmont, CA (US); Thomas W. Kenny, San Carlos, CA (US)

Correspondence Address: HAVERSTOCK & OWENS LLP, 162 NORTH WOLFE ROAD, SUNNYVALE, CA, 94086, US

(73) Assignee: Cooligy, Inc.

(21) Appl. No.: 10/746,223

(22) Filed: Dec. 24, 2003

Related U.S. Application Data
(63) Continuation-in-part of application No. 10/680,324, filed on Oct. 6, 2003.
(60) Provisional application No. 60/444,269, filed on Jan. 31, 2003.
(60) Provisional application No. 60/462,245, filed on Apr. 11, 2003.

(51) Int. Cl. H05K 7/20; F28F 7/00

(52) U.S. Cl. 361/704; 361/688; 165/76; 165/80.2

(57) ABSTRACT

A mounting assembly comprises a rigid support bracket configured to substantially surround a heat source. The rigid support bracket is coupled to a circuit board. The mounting assembly also comprises a removable lid that is coupled to the rigid support bracket and configured to provide selective access to the heat source. The mounting assembly further comprises a heat exchanger coupled to the heat source, wherein the heat exchanger is positioned between the heat source and the removable lid. The removable lid is preferably configured and has a desired stiffness to urge the heat exchanger in contact by a substantially constant force with the heat source and prevents unwanted movement of the heat source. Further, the support bracket structure is configured to transfer the substantially constant force over a relatively large surface area on the circuit board thereby protecting the heat source from bending, breaking or collapsing from the substantially constant force. The removable lid is preferably made of a material, including but not limited to copper, which accommodates a desired amount of heat transfer from an area within the support bracket.

### RELATED APPLICATION

This Patent Application is a continuation in part of U.S. patent application, Ser. No. 10/680,324, filed Oct. 6, 2003 and entitled, “DECOUPLED SPRING-LOADED MOUNTING APPARATUS AND METHOD OF MANUFACTURING THEREOF”, hereby incorporated by reference, which claims priority under 35 U.S.C. 119(e) of the co-pending U.S. Provisional Patent Application, Serial No. 60/444,269 filed Jan. 31, 2003, and entitled “REMEDIES FOR FREEZING IN CLOSED-LOOP LIQUID COOLING FOR ELECTRONIC DEVICES”. The U.S. Provisional Patent Application, Serial 60/444,269 filed Jan. 31, 2003, and entitled “REMEDIES FOR FREEZING IN CLOSED-LOOP LIQUID COOLING FOR ELECTRONIC DEVICES” is also hereby incorporated by reference. This Patent Application also claims priority under 35 U.S.C. 119(e) of the co-pending U.S. Provisional Patent Application, Serial No. 60/462,245, filed Apr. 11, 2003, and entitled “RING STIFFENER PROTECTOR AND REMOVABLE SPREADER LID”. The co-pending U.S. Provisional Patent Application, Serial No. 60/462,245, filed Apr. 11, 2003, and entitled “RING STIFFENER PROTECTOR AND REMOVABLE SPREADER LID” is hereby also incorporated by reference.

### FIELD OF THE INVENTION

The invention relates to an apparatus for securing components of a cooling system in general, and specifically, to a removable spreader support mechanism and method of manufacturing thereof.

### BACKGROUND OF THE INVENTION

Closed fluid loops are used in cooling electronic devices, such as a microprocessors in a computer. The fluid loop includes a heat exchanger which is placed in contact with the microprocessor as well as a heat rejector and pump coupled to the heat exchanger by one or more fluid tubes. FIG. 1 illustrates an existing fluid loop assembly 10. As shown in FIG. 1, the assembly 10 includes the heat exchanger 12 having a protruding tongue 14 and a pair of attach legs 20 extending from the body of the heat exchanger 12. In addition, the assembly 10 includes a substantially larger heat rejector 16 that is coupled to the heat exchanger 12 by at least 2 fluid tubes 18, whereby the heat rejector 16 includes a pair of attach legs 24 extending therefrom. The components in the assembly 10 are rigidly connected to one another to form one rigid assembly 10. As shown in FIG. 1, the microprocessor 14 is attached to a printed circuit board 22 by conventional means. The heat exchanger 12 of the assembly 10 is placed in contact with the microprocessor 26 and secured thereto by inserting the tongue 14 under a retaining member 28 and screwing the attach legs 20 into the printed circuit board 22 using screws 99. In addition, the attach legs 24 of the heat rejector 16 are also screwed into the printed circuit board 22 using screws 99.

The system is thereby rigidly attached to the printed circuit board 22, whereby, the fluid tubes 18 which connect the heat exchanger 12 to the heat rejector 16 are rigid and cannot move independently of one another with respect to circuit board. In other words, the components of the assembly shown in FIG. 1 are configured such that the assembly 10 does not incorporate any tolerance and is not flexible to respond to sudden movements. The stiffness and rigidity of the assembly 10 in FIG. 1 thus makes the assembly 10 susceptible to cracking or breaking whenever the printed circuit board 22 undergoes sudden movements or is dropped. In addition, the inability of the individual components in the assembly 10 to independently move or tolerate movement often causes the heat exchanger 12 to come out of or lose contact with the microprocessor 26 when subjected to sudden movements. Additionally, sudden movements experienced by the assembly 10 may cause the heat grease or thermal interface material between the heat exchanger 12 and microprocessor 26 to move, thereby making the heat exchanger 12 less effective in removing heat from the microprocessor 26. Any of the above scenarios can be detrimental to the electronic device utilizing the closed fluid loop within.

In addition, as shown in FIG. 1, the printed circuit board 22 does not have any additional support which protects the circuit board from shock or damage during assembly. The assembly 10 attached to the printed circuit board 22 has a substantial mass which may cause the circuit board 22 to bend or crack in the event that the circuit board 22 is subjected to sudden movements. In addition, the heat exchanger 12 in the assembly is exposed and is not protected from colliding with an adjacent component in the printed circuit board if subjected to a sudden movement.

FIGS. 2A-B illustrate examples of current microprocessor packaging assemblies. As shown in FIG. 2A, the microprocessor 34 is disposed within a package 32, whereby the package 32 and microprocessor are coupled to the circuit board 30. A heat spreader element 38 is coupled to the microprocessor 34 and the package 32 by a thermal adhesive, such as a thermal interface material 36. Alternatively, the spreader is rigidly attached to the package 32 using epoxy, fasteners or any other rigid attachment. A cooling component 40, such as a heat sink, is coupled to the heat spreader 38 by an adhesive or a thermal interface material, whereby the heat from the microprocessor 34 propagates through the heat spreader 38 to the heat sink 40. Although this assembly is widely used in the industry, it has several disadvantages. For instance, a large and heavy component such as a heat sink 40 will apply force directly to the microprocessor 34 via the heat spreader 38. Although the package 32 surrounds the microprocessor 34, the package 32 does not provide adequate support from the forces applied by the heat sink 40, inertial shock, thermal expansion or assembly stress. Such forces lead to very large, time dependent stress to the microprocessor 34 and the interconnect layers 31. In addition, the assembly shown in FIG. 2 does not provide easy access to the microprocessor 34, because the heat spreader 38 and heat sink 40 are attached by an adhesive.

Similarly, as shown in FIG. 2B, the microprocessor 34 is disposed within a package 32, whereby the package 32 and microprocessor are coupled to the circuit board 30. Unlike the device illustrated in FIG. 2A, the package 32 shown in FIG. 2B also comprises an integrated heat spreader element. In other words, the package 32 comprises a monolithic heat spreader element. The microprocessor 34 and the package 32 are coupled by a thermal adhesive, such as a thermal interface material 36. A cooling component 40, such as a heat sink, is coupled to the package 32 by an adhesive or a thermal interface material, whereby the heat from the microprocessor 34 propagates through the package 32 to the heat sink 40.

The assembly illustrated in FIG. 2B is also widely used in the industry but also has several disadvantages. Specifically, the load from the heat sink 40 is carried directly by the processor 34 comprising an integrated heat spreader element. To function, the assembly comprises a high thermal conductive material (copper, for example) but needs to remain thin (e.g.,<3.0 millimeters). Thus, the current assembly is flexible and ductile, and cannot protect the microprocessor 34 and the interconnect layers 31 from the variable mechanical loads (due to assembly and handling shocks, for example) transmitted from the heat sink 40. Further, this assembly does not allow for the removal of the heat spreader element because the heat spreader is integrated into the package 32.

What is needed is an assembly which provides stiffness support to the printed circuit board proximal to the area where the cooling system is positioned. What is also needed is an assembly which protects the heat exchanger and electronic device module and offers heat spreading capabilities. What is also needed is an assembly which allows access to the heat exchanger and electronic device.

### SUMMARY OF THE INVENTION

One aspect of the invention is directed to a mounting assembly which comprises a rigid support bracket that is configured to substantially surround a heat source. The rigid support bracket is coupled to a circuit board. The mounting assembly also comprises a removable lid that is coupled to the rigid support bracket and configured to provide selective access to the heat source.

Another aspect of the invention is directed to a system which controls a temperature of an electronic device that is coupled to a circuit board. The system comprises a mount which is coupled to the circuit board and covers at least the electronic device. The system is also configured to selectively provide access to the electronic device.

Another aspect of the invention is directed to a method of assembling a mounting assembly which protects an electronic device that is coupled to a circuit board. The method comprises the steps of coupling a support bracket structure to the circuit board, wherein the support bracket structure substantially surrounds the electronic device. The method also comprises coupling a removable lid to the support bracket structure, wherein the removable lid is configured to provide selective access to the electronic device.

In each of the above embodiment, the mounting assembly further comprises a heat exchanger that is coupled to the heat source, wherein the heat exchanger is positioned between the heat source and the removable lid. The removable lid is preferably configured and has a desired stiffness to urge the heat exchanger in contact by a substantially constant force with the heat source and prevents unwanted movement of the heat source. The removable lid is preferably made of a material, including but not limited to copper, which accommodates a desired amount of heat transfer from an area within the support bracket. The mounting assembly further comprises a resilient member that is coupled to the support bracket and is in contact with the removable lid, wherein the resilient member applies a consistent force to the removable lid.

In one embodiment, removable lid is coupled to the support bracket by a snap fit. Alternatively, the removable lid includes a plurality of resilient fingers along at least one edge of the removable lid, wherein the resilient fingers fit within a receiving slot in the support bracket. In one embodiment, the removable lid is circular shaped wherein the removable lid is removed from the support bracket by rotating the removable lid in a predetermined direction. In another embodiment, the removable lid is rectangular shaped. In one embodiment, the removable lid is removable from the support bracket by an external tool, wherein the removable lid further comprises at least one engaging feature for mating with a corresponding mating feature in the external tool. In one embodiment, the removable lid is coupled to the support bracket by sliding the removable lid along a guiding section of the support bracket. The removable lid further comprises at least one protrusion to be inserted into a receiving slot in the support bracket, whereby the protrusion allows engagement and disengagement of the removable lid with the support bracket. Alternatively, the removable lid further comprises at least one slot that is configured to be receive a protrusion in the support bracket, whereby the slot allows engagement and disengagement of the removable lid with the support bracket. The support bracket preferably further comprises a first portion which is coupled to the circuit board and configured to secure a portion of the removable lid. The support bracket also preferably includes a second portion which is adapted to be coupled to the first portion, wherein the second portion is configured to exert only a vertical force to the removable lid when coupled to the first portion.

### BRIEF DESCRIPTION OF THE DRAWINGS

FIG. 1 illustrates a perspective view of a prior art closed loop fluid system assembly.

FIG. 2A illustrates a schematic of a prior art microprocessor packaging assembly.

FIG. 2B illustrates a schematic of a prior art microprocessor packaging assembly.

FIG. 3 illustrates a schematic of one embodiment of the mounting assembly in accordance with the present invention.

FIG. 4 illustrates a schematic of one embodiment of the mounting assembly in accordance with the present invention.

FIG. 5A illustrates a perspective view of one embodiment of the mounting assembly in accordance with the present invention.

FIG. 5B illustrates a cross-sectional view of the embodiment in FIG. 5A along section B-B in accordance with the present invention.

FIG. 5C illustrates a perspective view of another embodiment of the mounting assembly in accordance with the present invention.

FIG. 6A illustrates a perspective view of another embodiment of the closure lid to be coupled to the support bracket in accordance with the present invention.

FIG. 6B illustrates a perspective view of the closure lid coupled to the support bracket in accordance with the present invention.

FIG. 6C illustrates a perspective view of another embodiment of the closure lid to be coupled to the support bracket in accordance with the present invention.

FIG. 7 illustrates an exploded view of another embodiment of the mounting assembly in accordance with the present invention.

FIG. 8A illustrates a perspective view of another embodiment of the closure lid to be coupled to the support bracket in accordance with the present invention.

FIG. 8B illustrates a cross sectional view of the embodiment along section C-C in accordance with the present invention.

FIGS. 9A-C illustrate perspective views of alternative embodiments of the mounting assembly in accordance with the present invention.

FIG. 10 illustrates a diagram of an alternative embodiment of the mounting assembly in accordance with the present invention.

FIG. 11 illustrates a diagram of an alternative embodiment of the mounting assembly in accordance with the present invention.

FIG. 12 illustrates a diagram of an alternative embodiment of the mounting assembly in accordance with the present invention.

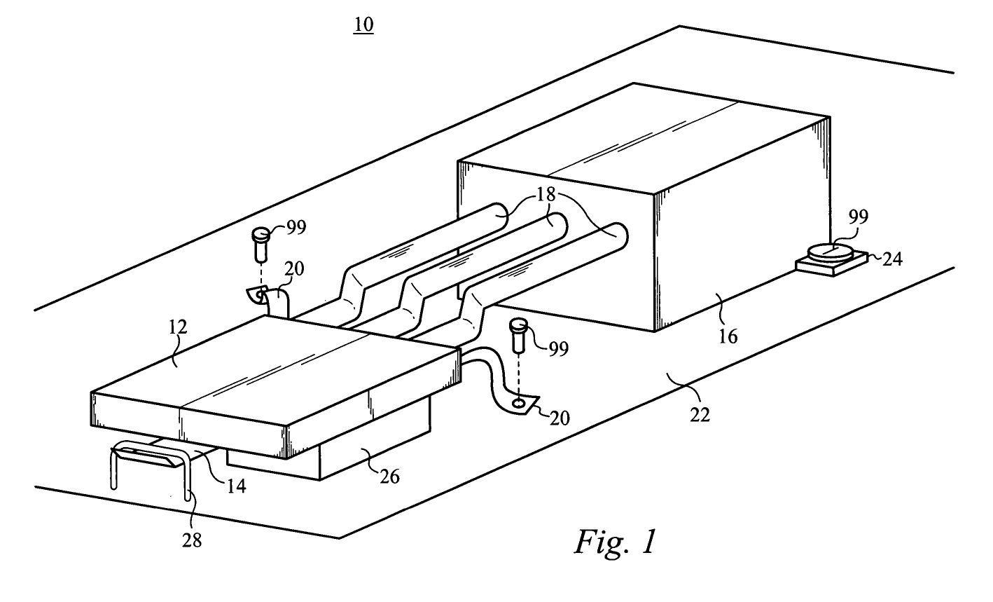

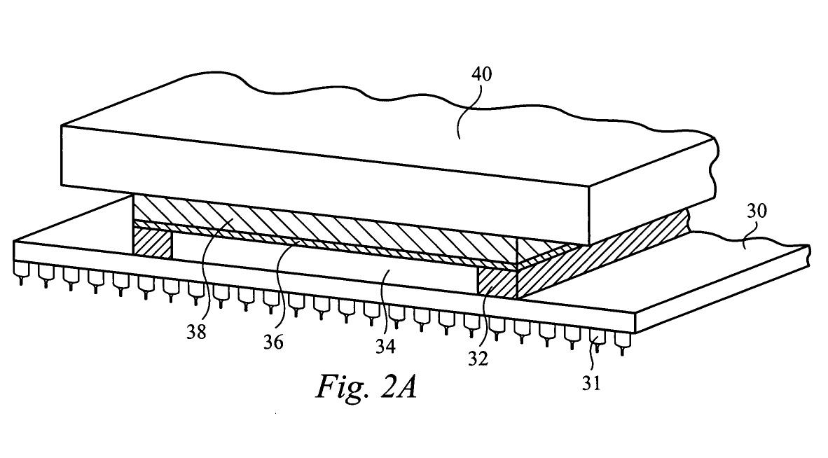

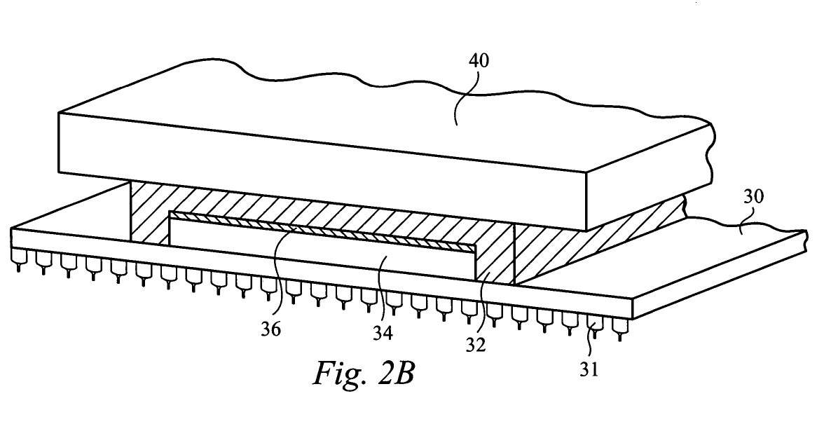

### DETAILED DESCRIPTION OF THE PRESENT INVENTION

It is apparent that although the mounting assembly of the present invention is described in relation to a cooling system, the present invention is alternatively applied to a heating system. In addition, although the mounting assembly is described to protect and support a microprocessor in a computer, it should be noted that the present invention can be used with other electronic devices or circuits inside a package or enclosure. For clarity purposes, the device being cooled is hereinafter referred to as a heat source or electronic device.

In the preferred embodiment, the present invention is directed to a mounting assembly which provides stiffness support to the surface which engages the cooling system and also provides access to the cooling system by utilizing a removable lid. The preferred mounting assembly also provides a heat spreading capability which aids in effective dissipation of heat generated by the cooling system and the electronic device. Alternatively, the mounting assembly applies a uniform securing force to maintain the heat exchanger in contact with the heat source or the electronic device. The securing force remains constant along the interface between the heat exchanger and electronic device irrespective of sudden movements which are experienced by the assembly or package which houses the assembly. In an alternative embodiment, the assembly allows the components to be mechanically decoupled and independently moveable so that the system is able to withstand sudden movements to the package.

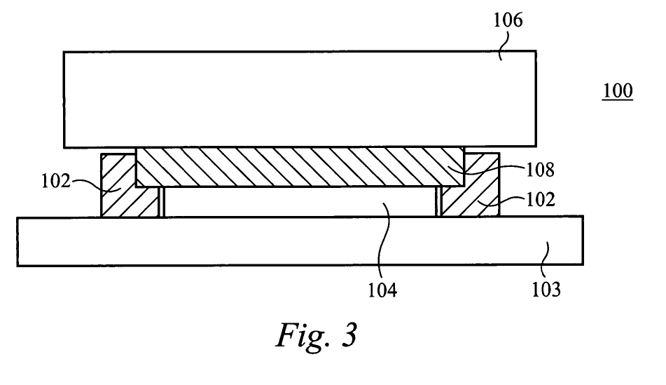

FIG. 3 illustrates a schematic of one embodiment of the mounting assembly 100 in accordance with the present invention. In particular, FIG. 3 illustrates a printed circuit board surface 103 with a microprocessor 104 coupled thereto. It is preferred that the microprocessor is coupled to a grid array, whereby the grid array is engaged with a socket that is disposed on the printed circuit board 103. However, for clarity, the socket for engaging a grid array as well as the grid array itself are not shown in FIG. 3. The mount support assembly 100 includes a support bracket 102 and a closure lid 108. The support bracket 102 is coupled to the printed circuit board 103 and is made of a rigid material. The closure lid 108 is coupled to the support bracket 102 and configured to be in contact with the microprocessor 104. As shown in FIG. 3, a large component 106 is placed on top of the closure lid 108. One example of the component 106 is a heat sink or any other relatively heavy structure which is coupled to the closure lid 108 and support bracket 102.

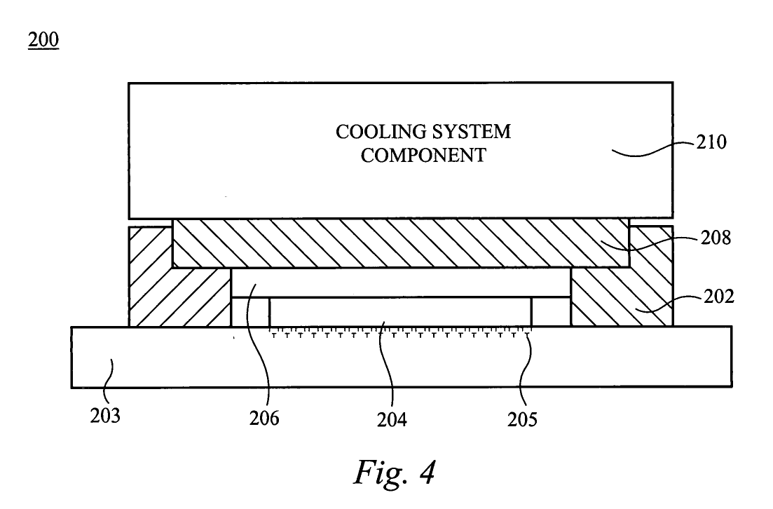

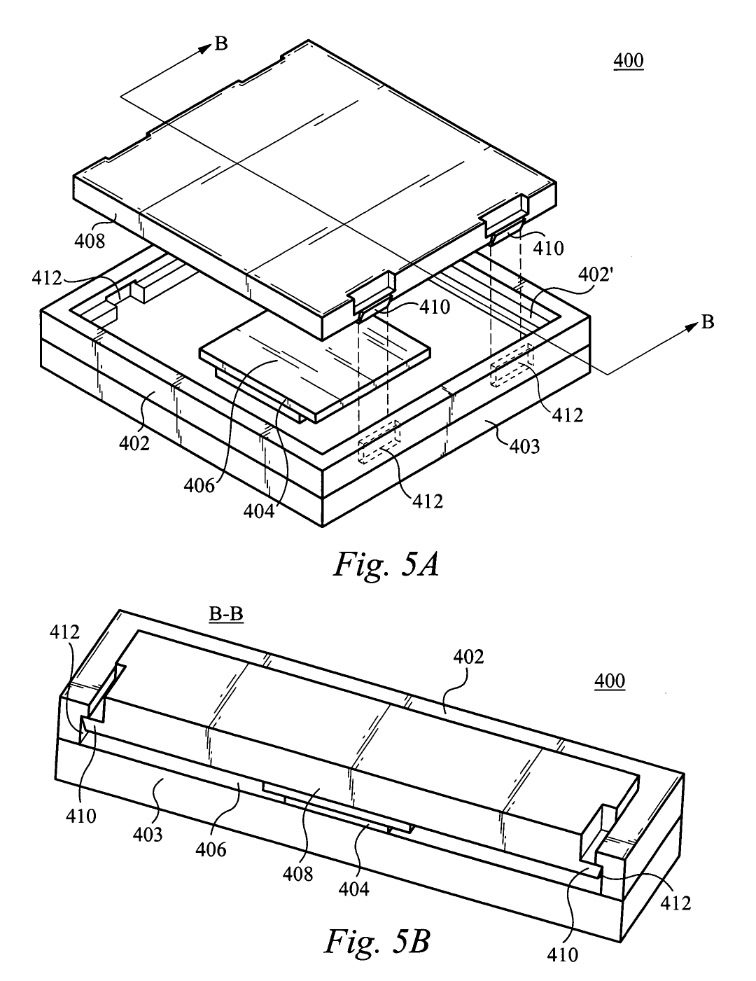

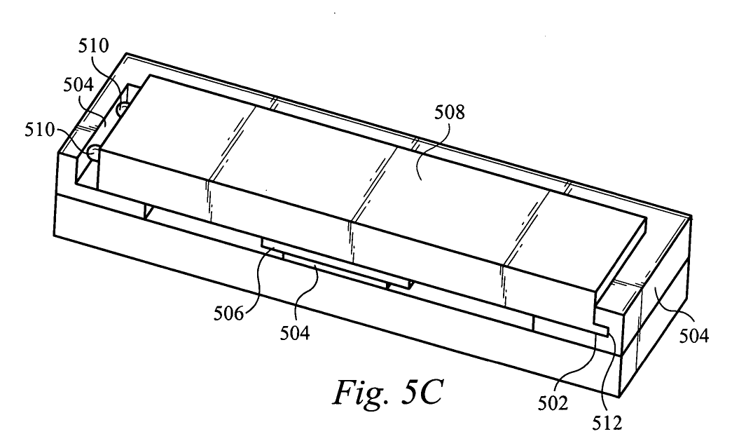

FIG. 4 illustrates a preferred embodiment of the mounting assembly 200 in accordance with the present invention. As shown in FIG. 4, the preferred embodiment includes a heat exchanger 206 coupled to the electronic device 204. The electronic device 204 is coupled to a grid array and socket, although FIG. 4 does not illustrate the grid array and socket for clarity purposes. The preferred mount support assembly 200 includes the support bracket 202 and the closure lid 208. The support bracket 202 is preferably rectangular shaped, as shown in FIG. 5A, although other shapes are contemplated. The inner sides of the support bracket 202 preferably have features which allow the closure lid 208 to be coupled thereto, as discussed in more detail below. The support bracket 202 is coupled to the printed circuit board 203 using any conventional techniques known to one skilled in the art. Alternatively, the support bracket 202 is coupled to any other appropriate surface or component.

As shown in FIG. 4, it is preferred that the mounting assembly 200 encloses or substantially encloses the electronic device 204 and heat exchanger 206. Alternatively, as shown in FIG. 3, the mounting assembly 100 encloses or substantially encloses the electronic device 104. In another alternative embodiment, the mounting assembly (not shown) encloses or substantially encloses the entire cooling system and electronic device (not shown) within, whereby the heat exchanger (not shown) operates as a “superheat-spreader” to external heat rejection devices outside of the mounting assembly (not shown).

It is preferred that the material of the support bracket 202 has a thermal expansion coefficient which substantially matches the thermal expansion coefficient of the electronic device 204 and heat exchanger 206. A substantial match in the thermal expansion coefficient prevents occurrence of thermal cycle stresses in the system due to the heating of the heat exchanger 206 and electronic device 204. Therefore, the support bracket 202 is preferably made from a metal, ceramic or plastic material, whereby the material has a relatively low thermal expansion coefficient. For example, for an electronic device made from silicon, the support bracket 202 comprises a material with a thermal expansion coefficient that matches the expansion coefficient of silicon.

The closure lid 208 couples to the support bracket 202 and preferably, as shown in FIG. 4, the closure lid 208 is pressed against the top surface of the heat exchanger 206 when the closure lid 208 is coupled to the support bracket 202.

The mounting assembly 200 of the present invention is configured to dissipate heat produced by the electronic device 204 captured by the heat exchanger 206. In the preferred embodiment shown in FIG. 4, the closure lid 208 presses the heat exchanger 206 into contact with the electronic device 204 with a constant force, and the heat is carried away by the fluid moving through the heat exchanger 206. In this embodiment, the closure lid 208 is primarily responsible for providing mechanical support and protection. Alternatively, as shown in FIG. 3, the closure lid 208 is pressed directly into against the top surface of the electronic device 204, and is responsible for transmitting heat from the electronic device 204 to the cooling system elements mounted on top of the closure lid 208. For example, a heavy heat rejector or other component 210 clamped directly on top of the mounting assembly 200 will apply large forces upon the mounting assembly 200. These forces applied to the electronic device 204 can occur from, but are not limited to, inertial shock to the entire structure, thermal expansion or assembly of the components onto the circuit board 203. The closure lid 208 and support bracket 202 transfer the load applied by the component 200 over a relatively large surface area on the circuit board 203 without changing the static force applied onto the electronic device 204 and heat exchanger 206. In addition, the support bracket 202 and closure lid 208 exhibit sufficient material strength to support the area enclosed within the mounting assembly 200 as well as the area around the perimeter of the assembly 200. The rigidness of the closure lid 208 and support bracket 202 thereby protects the electronic device 204, the interconnects 205 and the printed circuit board 203 from bending, breaking or collapsing from the applied forces. The mounting assembly 200 therefore provides a structural support path from the circuit board 203 to the structure or component disposed on the mounting assembly 200.

In the embodiment shown in FIG. 4, a heat exchanger 206 is positioned in contact with the electronic device 204 under the closure lid 208. This heat exchanger 206 is intended to capture all of the heat from the electronic device 204, and to carry that heat away by heating a fluid that enters and leaves the package. In this case, the closure lid 208 may also contribute to the heat removal, but it should be understood that the closure lid's 208 primary objective is to provide mechanical protection for the electronic device 204 and heat exchanger 206, and to apply a constant downward force on the heat exchanger 206.

The closure lid 208 is configured to withstand shocks from handling or assembly, and is not comprised from a brittle material. Thus, the closure lid 208 is preferably made of a metallic material, such as copper, aluminum, nickel, steel, or any other metallic material that can provide high stiffness and resistance to cracking. Alternatively, the closure lid 208 comprises impregnated composites to provide high mechanical strength and some thermal conduction. Alternatively, the closure lid 208 may incorporate fluidic or two-phase heat spreading technology, including but not limited to vapor chambers, heat pipes, capillary-pumped loops and the like; whereby the closure lid 208 is able to move heat from one or more concentrated regions to a larger fraction of the surface for efficient heat rejection.

Yet another alternative embodiment includes a configuration where the closure lid 208 is in contact with the electronic device 204 and dissipates heat away from the electronic device 204, as shown in FIG. 3. In this alternative embodiment, the closure lid 208 comprises a conductive material allowing the closure lid 208 to perform as a heat spreader. Examples of conductive materials that may be used include but are not limited to copper, aluminum, nickel, silicon, silicon carbide, aluminum nitride and diamond.

It is preferred that the closure lid 208 is larger in the length and width dimensions than the heat exchanger 206 (FIG. 4) and/or the electronic device 104 (FIG. 3). Alternatively, the closure lid 208 has the same length and width dimensions of the heat exchanger 206 (FIG. 4) and/or the electronic device 104 (FIG. 3). The closure lid 208 has a thickness which allows optimum spreading capabilities and load support to allow efficient operation of the electronic device 204 and the heat exchanger 206.

In the case of the embodiment shown in FIG. 3, the closure lid 108 is configured to carry all of the heat out of the package, and the thickness of the closure lid 208 is in the range of 0.2 to 1.0 millimeters, and overlaps the electronic device 204 (e.g., a microprocessor) by 1.0 to 10.0 millimeters on each side. These dimensions are selected to allow efficient spreading of the heat from the device to the outer surface of the package for efficient rejection throughout the heatsink.

In the case of the embodiment shown in FIG. 4, the closure lid 208 is configured to primarily provide mechanical support and protection, and some heat rejection. The thickness of the closure lid 208 illustrated in FIG. 4 is in the range of 0.5 to 5.0 millimeters, and overlaps the electronic device 204 (e.g., a microprocessor) millimeters on each side. These dimensions are selected to provide the necessary mechanical support within a small, rigid package. Other thickness dimensions are contemplated based on several factors including but not limited to the size of the electronic device 204, the material of the closure lid 208, and the interface thermal characteristics.

The closure lid 208 is also designed to be easily removable from the support bracket 202 to allow access to the contents within the area enclosed by the support bracket 202. The removable closure lid 208 allows the heat exchanger 206 and/or the electronic device 204 to be easily removed and replaced. The removability of the closure lid 208 allows the closure lid 208 to be easily replaced with a different closure lid 208 having different thermal conductivity or material strength characteristics.

The details of the different coupling mechanisms of the closure lid 408 and support bracket 402 will now be discussed. FIG. 5A illustrates a perspective view of the preferred mount support assembly in accordance with the present invention. As shown in FIGS. 5A and 5B, one embodiment of the mounting assembly 400 includes the closure lid 408 coupled to the support bracket 402 by a snap fit. In particular, the closure lid 408 in FIGS. 5A and 5B includes two slanted protrusions 410 located along opposing side walls. The support bracket 402 includes two receiving notches 412 positioned in the corresponding inner side walls which are configured to accept the slanted protrusions 410. The slanted protrusions 410 engage the receiving notches 412 and provide a snap fit when the closure lid 408 is pressed downward into the support bracket 402. In addition, as shown in FIG. 5B, the area above the notches 412 along the inner wall of the support bracket 402 extends slightly toward the closure lid 408 to prevent the closure lid 408 from unintentionally being disengaged from the support bracket 402. It should be noted that although the closure lid 408 is shown to have four protrusions 410, any number of protrusions are contemplated. Similarly, although the support bracket 402 is shown to have four notches 412, any number of notches are contemplated. An appropriate tool (not shown) is used to remove the closure lid 408 from the support bracket 402, whereby the tool (not shown) provides enough clearance between the protrusions 410 and notches 412 to lift the closure lid 408 out from the support bracket 402.

The closure lid 408 and support bracket 402 are preferably configured to transfer a load (i.e., an applied force), applied by the component (not shown) or the closure lid 408, for example, over a relatively large surface area on the circuit board without changing the static force applied onto the electronic device 404 and heat exchanger 406. In addition, the support bracket 402 and closure lid 408 exhibit sufficient material strength to protect the electronic device 404, and the corresponding interconnects and the printed circuit board (not shown) from bending, breaking or collapsing from the applied forces. In one embodiment, the closure lid 408 and support bracket 402 transfer the applied force over a relative large surface area on the circuit board 203 via a ledge 402′. It should be understood that the ledge 402′ is but one example of configurations available allowing the closure lid 408 and support bracket 402 to transfer an applied force over a relatively large surface area without changing the static force applied onto the electronic device 404 and heat exchanger 406.

In another embodiment, as shown in FIG. 5C, the closure lid 508 includes one or more button-like protrusions 510 along one or more sides to secure the closure lid 508 to the support bracket 504. In addition, as shown in FIG. 5C, the closure lid 508 includes a stamped edge 502 which fits within the corresponding recess 512 in the inner side of the support bracket 504. The button protrusions 510 provide frictional contact along the inner wall opposite of the recess 512 in the support bracket 504 to secure the closure lid 508 to the support bracket 504. It is apparent to one skilled in the art that the closure lid 508 alternatively has any number of button protrusions 510 extending from any of the sides of the closure lid 508. To remove the closure lid 508 from the bracket 504, an external tool is guided toward the bottom edge of the closure lid 508 and between the protrusions 510. The external tool then catches the bottom edge of the closure lid 508 and pulls the lid 508 upward in essentially the opposite direction as when the closure lid 508 is coupled to the bracket 504.

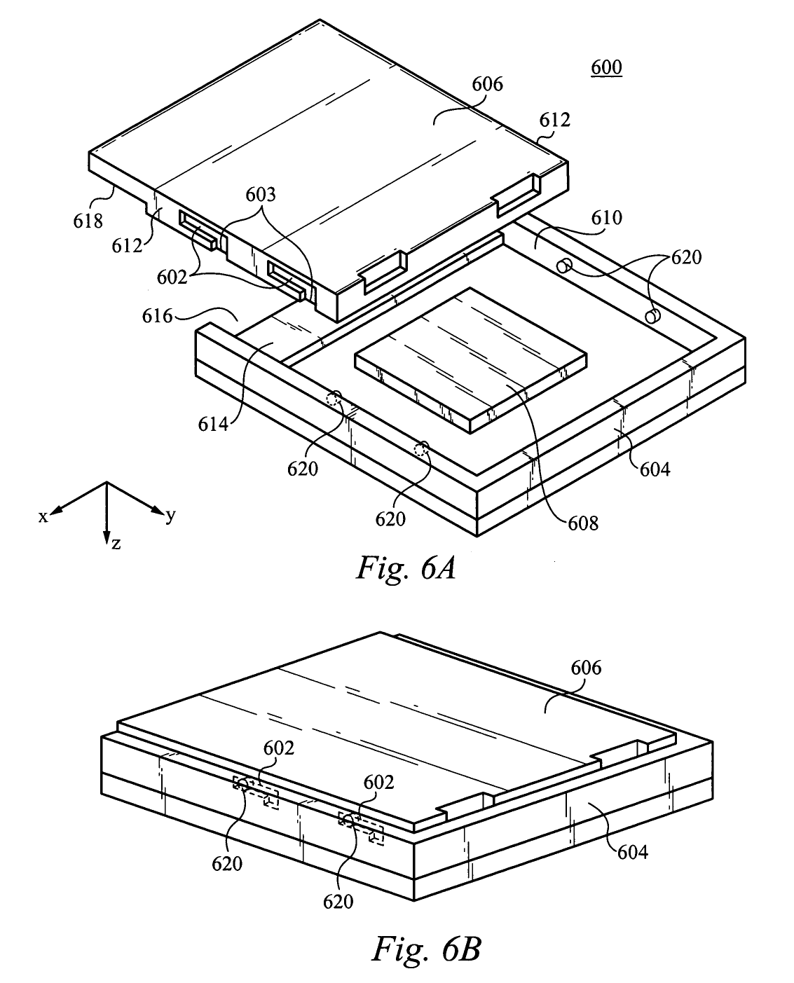

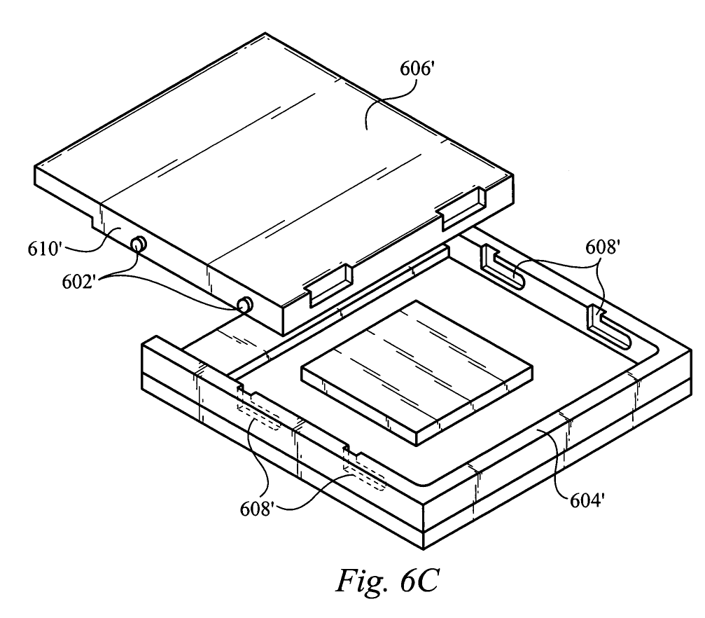

FIGS. 6A-B illustrate another embodiment of the mounting assembly 600 in accordance with the present invention. In the embodiment shown in FIGS. 6A-B, the closure lid 606 is coupled to the support bracket 604 by “dropping” the closure lid 606 into the support bracket 604 in the Z direction and “sliding” the closure lid 606 along the X direction into engagement with the support bracket 604. The support bracket 604 includes four peripheral inner sides 610 which includes a number of protrusions 620 extending therefrom. In addition, the support bracket 604 includes a lateral entry area 616, whereby a raised portion 614 proximal to the lateral entry area 616 secures the closure lid 606 to the support bracket 604.

The body of the closure lid 606 includes four outer peripheral sides 612 which contact the inner sides 610 of the support bracket 604 when the closure lid 606 is coupled to the support bracket 604 (FIG. 6B). As shown in FIG. 6A, one side 602 of the closure lid 606 includes two inverted “L” grooves 602. In one embodiment, the closure lid 606 includes grooves 602 along opposing sides 612. Alternatively, the closure lid 606 includes grooves 602 along only one side 612. The protrusions 620 along the inner sides 610 are configured to be inserted into the corresponding grooves 602 as the closure lid 606 is coupled to the support bracket 604.

In particular, the closure lid 606 is coupled to the support bracket 604 by first placing the closure lid 606 onto the support bracket 604. The closure lid 606 is placed in a “dropped position” by moving the closure lid 606 along the Z direction. As the closure lid 606 is moved along the Z direction, the protrusions 620 are aligned with the grooves 602 and are inserted into the opening or entry 603 of the grooves 602. The closure lid 606 is slid along the X direction parallel to the plane that the grooves 602 are configured along, whereby the protrusions 620 are guided along the grooves 602 in the X-direction. It is desired that the dimensions and configurations of the inverted “L” grooves 602 are such that the bottom surface of the closure lid 606 does not come into contact with the heat exchanger or electronic device while the closure lid 606 is moved in the X direction. The closure lid 606 is slid along the X direction until the stepped portion 618 of the closure lid 606 registers with the raised portion 614 of the support bracket 604, wherein the closure lid 606 then sets vertically and the bottom surface of the closure lid 606 comes into contact with the heat exchanger or electronic device. The closure lid 606 is then securely coupled to the support bracket 604, whereby the protrusions 620 are positioned near the ends of the grooves 602, as shown in FIG. 6B.

To remove the closure lid 606 from the support bracket 604, the closure lid 606 is slid in the X direction opposite of that when the closure lid 606 was coupled to the support bracket 604. As the closure lid 606 is slid in the opposite direction, the stepped portion 618 comes out of contact with the raised portion 614 of the support bracket 604 and the protrusions 620 are guided along the grooves 602 in the direction toward the openings 603. Once the protrusions 620 are positioned in the openings 603 of the grooves 602, the closure lid 606 is able to be lifted in the opposite Z direction and removed from the support bracket 604. The removed lid 606 thereby allowing access to the contents, namely the heat exchanger 608 and electronic device, within the area surrounded by the support bracket 604.

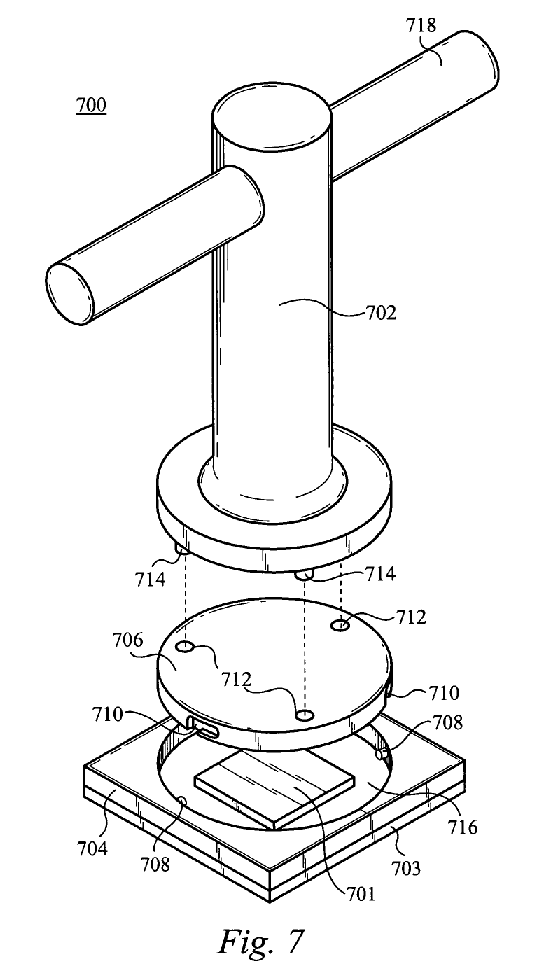

It is apparent to one skilled in the art that the stepped and raised surfaces are not necessary to the present invention. It is also noted that the above embodiment illustrates one example of how the closure lid is coupled to the support bracket. For instance, as shown in FIG. 6C, the closure lid 606′ alternatively includes protrusions 602′ which extend from the sides 610′. In addition, the support bracket 604′ includes “L” shaped grooves 608′ along its inner surface, whereby the protrusions 602′ are received in the grooves 608′ to secure the closure lid 606′ to the support bracket 604′. Although the closure lid is shown to be square or rectangular shape in the above figures, it is contemplated that the closure lid alternatively has a circular or other shape, as shown in FIG. 7. Preferably, the designs shown in FIGS. 6A-C comprise a support bracket, similar to the support bracket 402 shown in FIG. 5A, configured to transfer the load from the closure lid to the support bracket.

FIG. 7 illustrates another embodiment of the mounting assembly 700 in accordance with the present invention. As shown in FIG. 7, the support bracket 704 is coupled to the printed circuit board 703 and includes a circular cavity 716 which accepts a circular closure lid 706 and includes a number of protrusions 708 extending toward the center of the cavity 716. The circular closure lid 706 performs the same functions as the closure lids described above in relation to FIGS. 5A-6C. The closure lid 706 includes several “L” shaped grooves 710 along the side surface that receive the protrusions 708. The specific operation of the grooves 710 and protrusions 708 is discussed above and is not again discussed herein.

The circular closure lid 706 shown in FIG. 7 is coupled to the support bracket 704 by an external tool or key 702. As shown in FIG. 7, the tool 702 includes a T-shaped handle 718 as well as a number of protrusions 714 on its bottom surface. The protrusions 714 on the bottom surface of the tool 702 are configured to fit within the corresponding alignment apertures 712 in the top surface of the closure lid 706. The tool 702 is thus able to turn or rotate the closure lid 706 in a desired direction when the protrusions 714 are coupled to the apertures 712 in the closure lid 706. In the embodiment shown in FIG. 7, the tool 702 couples the closure lid 706 to the support bracket 704 by rotating the closure lid 706 in a clockwise motion. Alternatively, the mounting assembly 700 is configured such that the closure lid 706 is coupled to the support bracket 704 by rotating the closure lid 706 in a counter-clockwise motion. In contrast, the tool 702 removes the closure lid 706 from the support bracket 704 by rotating the closure lid 706 in the direction opposite of that for coupling the closure lid 706 to the support bracket 704. Preferably, the design shown in FIG. 7 comprises a support bracket, similar to the support bracket 402 shown in FIG. 5A, configured to transfer the load from the closure lid 706 to the support bracket 704.

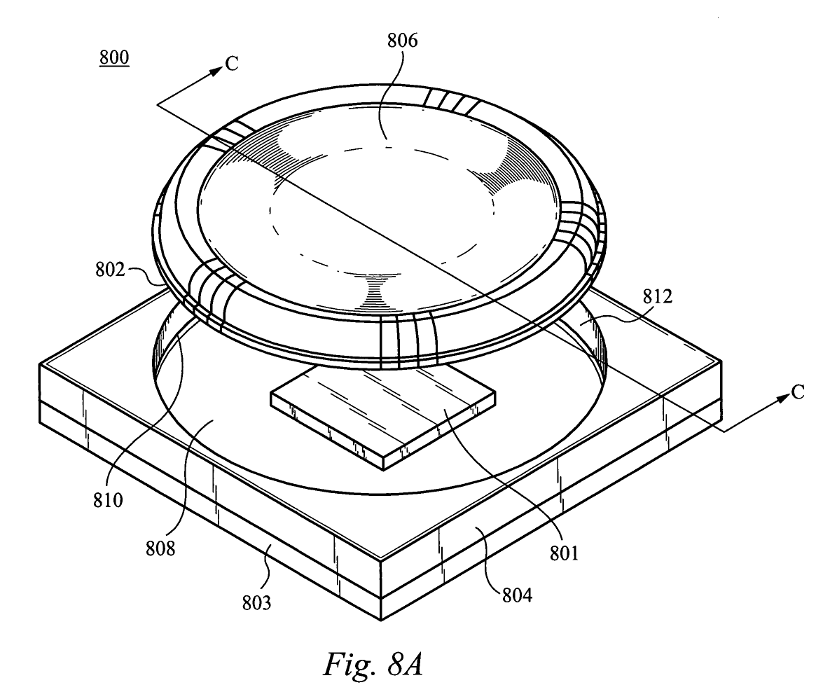

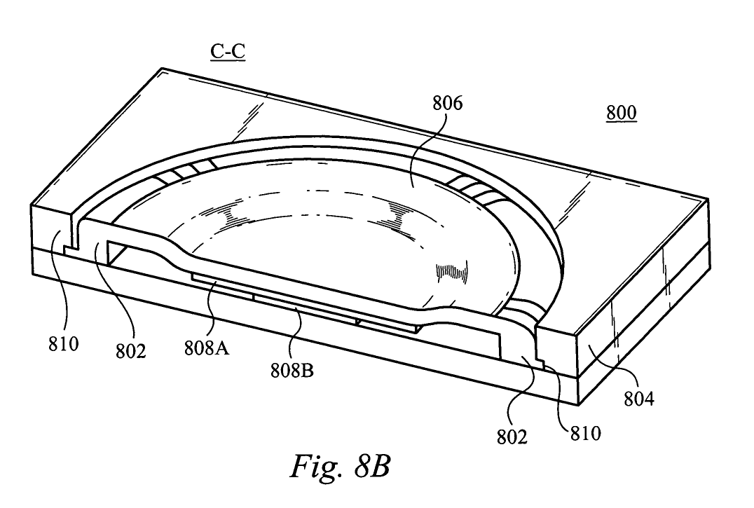

FIGS. 8A and 8B illustrate a perspective and cross-sectional view of another embodiment of the mounting assembly in accordance with the present invention. As shown in FIG. 8A, the support bracket 804 is coupled to the printed circuit board 803 and includes a circular cavity 808 configured to receive the circular closure lid 806. As shown in FIGS. 8A and 8B, the electronic device and heat exchanger 801 are located within the cavity 808. In addition, the support bracket 804 includes a receiving slot 810 configured along the inner surface 812 facing the cavity 808, whereby the receiving slot 810 receives the fingers 802 of the closure lid 806.

The closure lid 806 in the embodiment shown in FIGS. 8A-8B includes a plurality of resilient spring-like fingers 802 disposed along the entire outer edge of the closure lid 806. In another embodiment, the closure lid 806 includes resilient spring-like fingers disposed along less than its entire outer edge. The resilient fingers 802 are configured to bend slightly as the closure lid 806 is coupled to the support bracket 804, whereby the fingers 802 naturally spring back into their natural shape when in communication with the receiving slot 810. In particular, the closure lid 806 is coupled to the support bracket 804 by pressing the closure lid 806 toward the cavity 808, whereby the fingers 802 bend slightly toward the center of the closure lid 806 as they contact the inner surface 810 of the support bracket 804. As the closure lid 806 moves downward toward the cavity 808, the fingers 802 reach the receiving slot 810 and spring back to their natural shape into registry with the slot 810, as shown in FIG. 8B. The closure lid 806 is thus coupled to the support bracket 804 by “popping” the closure lid 806 into the support bracket 804.

As shown in FIGS. 8A and 8B, the closure lid 806 is configured to have an indentation along its top surface, whereby the indentation applies a consistent force upon the heat exchanger 801 to secure the heat exchanger 801 to the electronic device. The closure lid 806 is configured and made of a material to perform the same actions of the clip (not shown) discussed above. In particular, as shown in FIG. 8B, the mid-section of the closure lid 806 bulges or extends downward toward the heat exchanger 801. It is contemplated by one skilled in the art that each of the above discussed closure lids are alternatively designed to have an indentation on its top surface as the closure lid 806 in FIGS. 8A and 8B. In the embodiment shown in FIGS. 8A-B, the lid applies a constant force to the heat exchanger and electronic device because of the spring-loading character of this design. In addition, it is possible to mount other elements of the heat rejection system on top of this closure lid. The advantage of this embodiment is that the loading forces arising due to the mounting of additional elements are applied only at the edge of the closure lid, and these forces are transmitted to the substrate 803 at the edge 802. The forces are not transmitted through the heat exchanger 808A and device 808B because the downward curvature of the closure lid prevents contact with the other elements of the heat rejection system over the heat exchanger and device. Preferably, the designs shown in FIGS. 8A-B comprise a support bracket, similar to the support bracket 402 shown in FIG. 5A, configured to transfer the load from the closure lid to the support bracket.

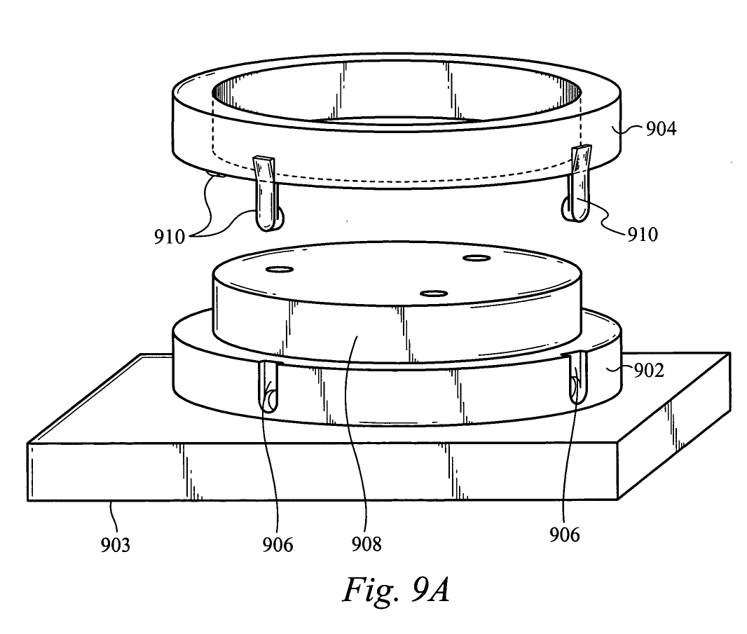

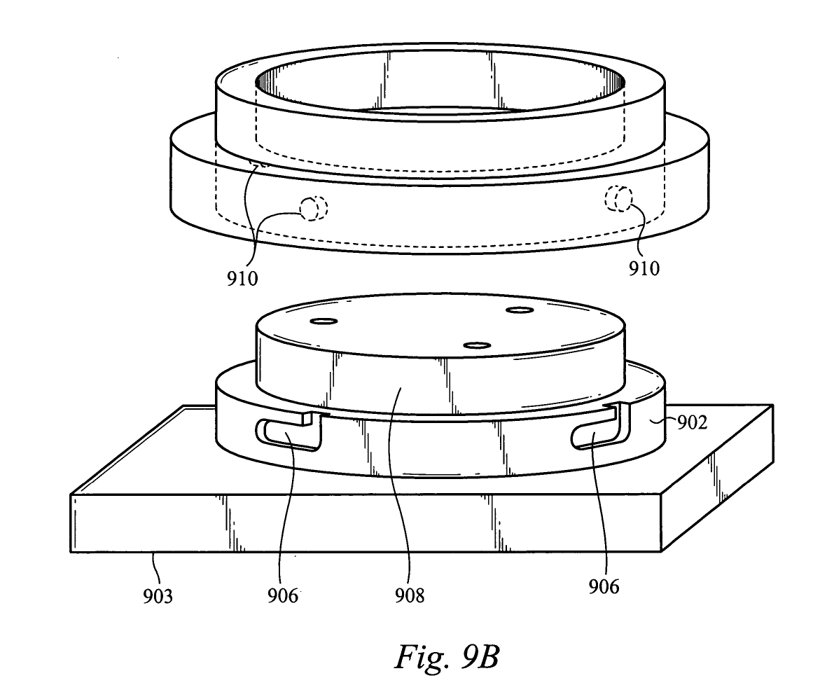

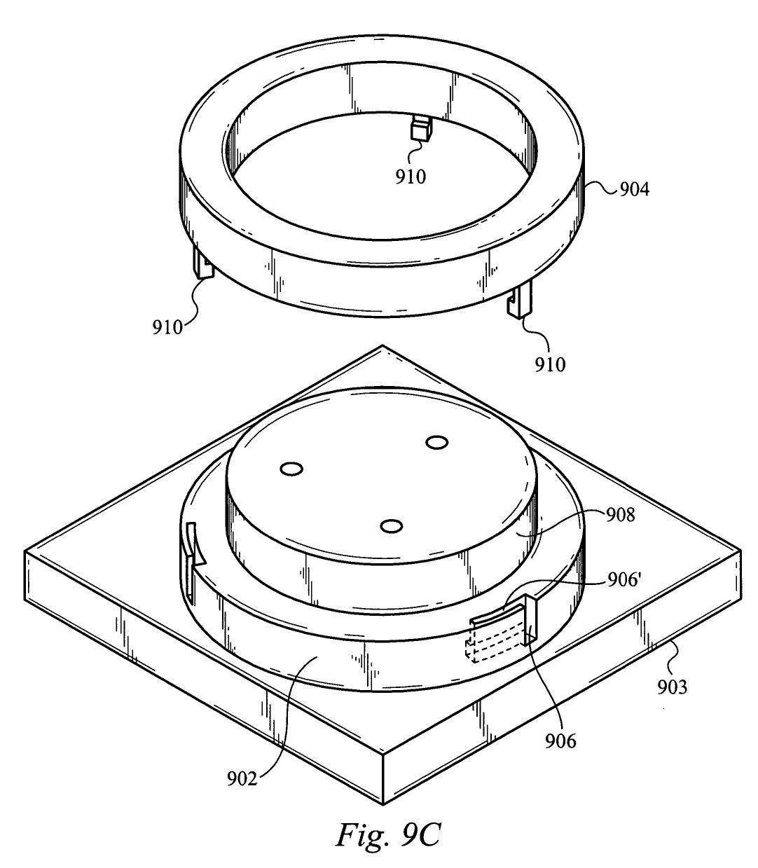

FIGS. 9A-C and 10-12 illustrate various alternative embodiments of the mounting assembly of the present invention. In the embodiment shown in FIGS. 9A-C, the bottom portion of the support bracket 902 is coupled to the printed circuit board 903. The closure lid 908 is coupled to the bottom portion 902 and is secured thereto, whereby the upper section of the closure lid 908 extends above the upper surface of the bottom portion 902. As shown in FIG. 9A, the bottom portion 902 includes at least one slot 906 along its outer surface to engage the top portion 904. The top portion 904 fits over the bottom portion 902 and includes a corresponding number of pins 910 which fit into the corresponding slots 906. The pins 910 hang from the bottom of the top portion 904 and protrude slightly inward, whereby the pins 910 fit into the entry of the slot 906. The embodiment shown in FIG. 9B illustrates the top portion 904 configured to allow rotatable and detachable coupling. This is performed when the pins 910 insert into and rotatably slide along the slot 906. Similarly, the embodiment shown in FIG. 9C allows the top portion to rotatably and detachably couple when the pins 910 are inserted into the slot 906 and rotatably slide along the slot channel 906′. Regardless of the embodiment, the top portion 904 is configured to drop vertically with the pins 910, configuring the closure lid 908 to come into contact with the inner surface of the top portion 904.

The embodiment shown in FIG. 9 prevents lateral, shear or torque forces from being exerted onto the closure lid 908 and microprocessor (not shown) as the top portion 904 is coupled to the bottom portion 902. Thus, the closure lid 908 and the microprocessor (not shown) only experiences vertical forces which do not damage the interconnects (not shown) of the microprocessor (not shown).

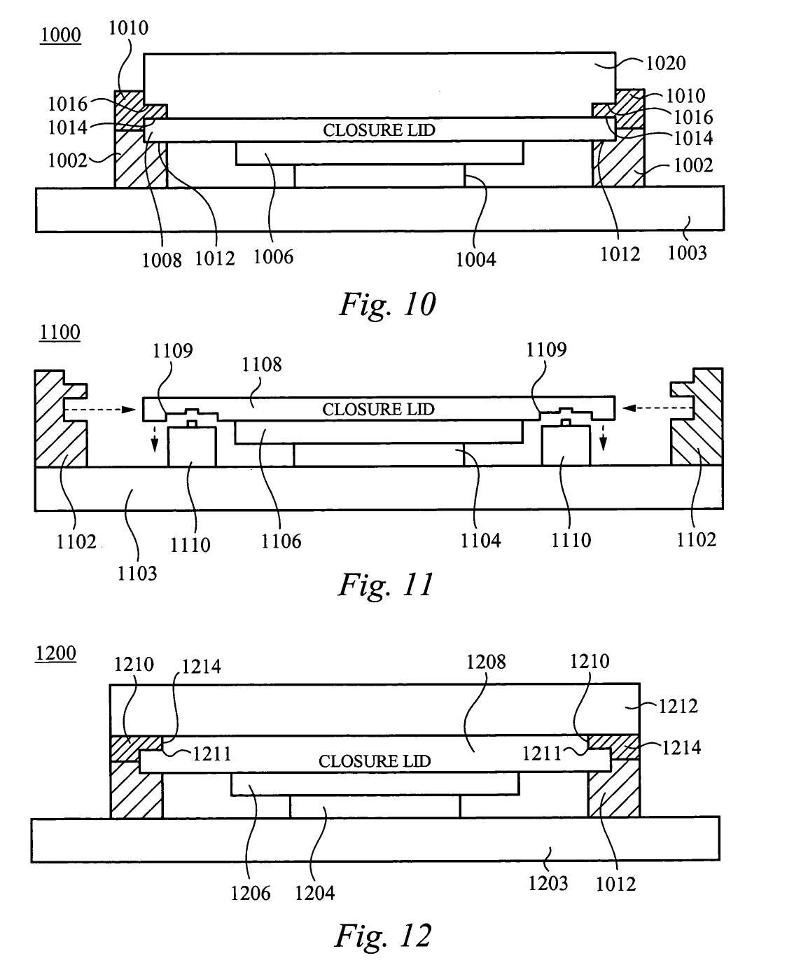

In the embodiment shown in FIG. 10, the mounting assembly 1000 in FIG. 10 includes the support bracket having a bottom portion 1002 and a top portion 1010 which is separably coupled to the bottom portion 1002. The bottom portion 1002 is coupled to the printed circuit board 1003 and surrounds the microprocessor 1004 and the heat exchanger 1006. As shown in FIG. 10, the bottom portion 1002 of the support bracket has a recess 1012 which allows the closure lid 1008 to sit thereon. The closure lid 1008 thereby is vertically placed into contact with the top surface of the heat exchanger 1006. The top portion 1010 of the support bracket is coupled to the top surface of the bottom portion 1002 by any method described above or any other known method in the art. The top portion 1010 has a notch 1014 which mates with the top surface of the closure lid 1008. The closure lid 1008 is thereby securely enclosed by the recess 1012 of the bottom portion 1002 and the notch 1014 of the top portion 1010. The top portion 1010 includes a recess 1016 along the top surface which allows the bottom surface of a cooling component 1020 to sit thereupon. The top and bottom portions 1010, 1002 of the support bracket secure the closure lid 1008 in contact with the heat exchanger 1006 and prevent the closure lid 1008 from moving laterally or horizontally as the cooling component 1020 is coupled to the assembly. Therefore, any lateral or torsion forces applied when the additional component 1106 is coupled to the top portion 1010 of the support bracket does not transfer to the closure lid 1008, the microprocessor 1004 and the heat exchanger 1006.

In the embodiment shown in FIG. 11, the mounting assembly 1100 is assembled by initially coupling the closure lid 1108 to the heat exchanger 1106. The alignment members 1110 are each side of the heat exchanger 1106 are inserted into the receiving slots 1109 in the bottom surface of the closure lid 1108. The alignment marks 1110 allow the closure lid 1108 to be vertically placed on top of the heat exchanger 1106 without undergoing any horizontal or lateral movement. Once the closure lid 1108 is secured to the heat exchanger 1106, the support bracket 1102 is coupled to the closure lid 1108 without disturbing the contact between the closure lid 1108 and the heat exchanger 1106. In one embodiment, as shown in FIG. 11, each side of the support bracket 1102 is laterally coupled to the closure lid 1108. The support bracket is coupled to the printed circuit board 1103 by any conventional method. It is contemplated by one skilled in the art that the support bracket 1102 is either one piece or is divided into a top and bottom portion, as shown in FIG. 10. The advantages of the embodiment in FIG. 11 are similar to that described in FIG. 10.

FIG. 12 illustrates another embodiment of the mounting assembly of the present invention. In the embodiment shown in FIG. 12, the closure lid 1208 includes one or more notches 1211 in the side walls. A perspective view of the notches 1211 in the side walls of the closure lid 1208 are shown in FIG. 5A. The top portion 1210 of the support bracket includes a corresponding number of protrusions 1214 which engage the notches 1211 in the closure lid 1208. The bottom portion 1202 of the support bracket has a support surface which secures the bottom of the closure lid 1208. The dimensions of the top portion 1210 allow the protrusions 1214 to press down upon the bottom surface of the notches 1211 and force the closure lid 1208 in contact with the heat exchanger 1206 and the support bracket 1202. Considering that the notches 1211 are recessed vertically into the side walls of the closure lid 1208 (FIG. 5A), the closure lid 1208 is flush with the top surface of the support bracket 1202 when assembled to the mount 1200. Therefore, the configuration shown in FIG. 12 allows another component 1212 to rest upon the mounting assembly and has the advantages of the embodiments shown in FIGS. 10 and 11.

A resilient clip is alternatively coupled to the support bracket and/or the closure lid to apply a constant downward force upon the closure lid and maintain the interface between the heat exchanger and electronic device in response to sudden movements experienced by the packaging. Details of the clip are discussed in co-pending U.S. patent application Ser. No. (Cool-02000), filed ______ which is hereby incorporated by reference. Alternatively, the clip (not shown) is directly in contact with the heat exchanger, whereby the removable lid is positioned over the clip (not shown).

The current invention provides mechanical support proximal to the area where the cooling system is positioned so that mechanical shocks are not transmitted to the die. The current assembly also protects the heat exchanger and electronic device module and offers heat spreading capabilities. Further, the current invention provides for easy access to and removal of a microchannel heat exchanger within the package under the spreader lid.

The present invention has been described in terms of specific embodiments incorporating details to facilitate the understanding of the principles of construction and operation of the invention. Such reference herein to specific embodiments and details thereof is not intended to limit the scope of the claims appended hereto. It will be apparent to those skilled in the art that modification s may be made in the embodiment chosen for illustration without departing from the spirit and scope of the invention.

What is claimed is:

1. A mounting assembly comprising:
a. a rigid support bracket configured to substantially surround a heat source, the rigid support bracket coupled to a circuit board; and
b. a removable lid coupled to the rigid support bracket and configured to provide selective access to the heat source.

2. The mounting assembly according to claim 1 further comprising a heat exchanger coupled to the heat source, wherein the heat exchanger is positioned between the heat source and the removable lid.

3. The mounting assembly according to claim 2 wherein the removable lid is configured to urge the heat exchanger in contact with the heat source.

4. The mounting assembly according to claim 1 wherein the removable lid prevents unwanted movement of the heat source.

5. The mounting assembly according to claim 1 wherein the rigid support bracket is further configured to transfer a substantially constant force applied onto the heat source over a relatively large surface area on the circuit board thereby protecting the heat source and the circuit board from bending, breaking or collapsing from the substantially constant force and without changing the substantially constant force applied onto the heat source.

6. The mounting assembly according to claim 1 wherein the removable lid is made of a material to accommodate a desired amount of heat transfer from an area within the support bracket.

7. The mounting assembly according to claim 6 wherein the material is copper.

8. The mounting assembly according to claim 1 wherein the support bracket and the removable lid are configured to maintain a substantially constant force upon the heat source.

9. The mounting assembly according to claim 2 wherein the removable lid has a desired stiffness value to maintain a substantially consistent force between the heat exchanger and the heat source.

10. The mounting assembly according to claim 1 further comprising a resilient member coupled to the support bracket and in contact with the removable lid, wherein the resilient member applies a consistent force to the removable lid.

11. The mounting assembly according to claim 1 wherein the removable lid is coupled to the support bracket by a snap fit.

12. The mounting assembly according to claim 1 wherein the removable lid includes a plurality of resilient fingers along at least one edge of the removable lid, wherein the resilient fingers fit within a receiving slot in the support bracket.

13. The mounting assembly according to claim 1 wherein the removable lid is circular shaped.

14. The mounting assembly according to claim 1 wherein the removable lid is rectangular shaped.

15. The mounting assembly according to claim 1 wherein the removable lid is removable from the support bracket by an external tool, wherein the removable lid further comprises at least one engaging feature for mating with a corresponding mating feature in the external tool.

16. The mounting assembly according to claim 1 wherein the removable lid is removed from the support bracket by rotating the removable lid in a predetermined direction.

17. The mounting assembly according to claim 1 wherein the removable lid is coupled to the support bracket by sliding the removable lid along a guiding section of the support bracket.

18. The mounting assembly according to claim 17 wherein the removable lid further comprises at least one protrusion for insertion into a receiving slot in the support bracket for allowing engagement and disengagement of the removable lid with the support bracket.

19. The mounting assembly according to claim 17 wherein the removable lid further comprises at least one slot configured to be receive a protrusion in the support bracket to allow engagement and disengagement of the removable lid with the support bracket.

20. The mounting assembly according to claim 1 wherein the support bracket further comprises:
a. a first portion coupled to the circuit board, the first portion configured to secure a portion of the removable lid; and
b. a second portion adapted to be coupled to the first portion, wherein the second portion is configured to exert only a vertical force to the removable lid when coupled to the first portion.

21. A system for controlling a temperature of an electronic device coupled to a circuit board comprising a mount coupled to the circuit board, the mount for covering at least the electronic device and configured to selectively provide access to the electronic device.

22. The system according to claim 21 wherein the mount further comprises:
a. a support bracket positioned to substantially surround the electronic device; and
b. a removable lid coupled to the support bracket and configured to apply a force to the electronic device.

23. The system according to claim 21 wherein the support bracket further comprises:
a. a first portion coupled to the circuit board, the first portion configured to secure a portion of the removable lid; and
b. a second portion adapted to be coupled to the first portion, wherein the second portion is configured to exert only a vertical force to the removable lid when coupled to the first portion.

24. The system according to claim 21 further comprising a heat exchanger coupled to the electronic device, wherein the heat exchanger is positioned between the electronic device and the removable lid.

25. The system according to claim 21 wherein the removable lid is configured to prevent undesired movement of the electronic device.

26. The system according to claim 21 wherein the removable lid is made of a material to accommodate a desired amount of heat transfer from within the mount.

27. The system according to claim 26 wherein the material is copper.

28. The system according to claim 21 wherein the support bracket and the removable lid are configured to maintain a substantially constant force upon the electronic device.

29. The system according to claim 28 wherein the support bracket is further configured to transfer the substantially constant force over a relatively large surface area on the circuit board thereby protecting the electronic device from bending, breaking or collapsing from the substantially constant force.

30. The system according to claim 21 wherein the removable lid has a desired stiffness value to maintain the heat exchanger in contact with the electronic device.

31. The system according to claim 21 further comprising a resilient member coupled to the mount, wherein the removable lid applies a consistent force upon the electronic device.

32. The system according to claim 21 wherein the removable lid is coupled to the support bracket by a snap fit.

33. The system according to claim 21 wherein the removable lid includes a plurality of resilient fingers along at least one edge, wherein the resilient fingers fit within a receiving slot in the support bracket.

34. The system according to claim 21 wherein the removable lid is circular shaped.

35. The system according to claim 34 wherein the removable lid is removed from the support bracket by rotating the removable lid in a predetermined direction.

36. The system according to claim 21 wherein the removable lid is rectangular shaped.

37. The system according to claim 21 wherein the removable lid is removed from the support bracket by an external tool, wherein the removable lid further comprises at least one engaging feature for mating with a corresponding mating feature in the external tool.

38. The system according to claim 21 wherein the removable lid is coupled to the support bracket by sliding the removable lid along a guiding section of the support bracket.

39. The system according to claim 38 wherein the removable lid further comprises at least one protrusion configured for insertion into a receiving slot in the support bracket for allowing engagement and disengagement of the removable lid with the support bracket.

40. The system according to claim 21 wherein the removable lid further comprises at least one slot configured to be receive a protrusion in the support bracket to allow engagement and disengagement of the removable lid with the support bracket.

41. A method of assembling a mounting assembly to protect an electronic device coupled to a circuit board, the method comprising the steps of:
a. coupling a support bracket structure to the circuit board, wherein the support bracket structure substantially surrounds the electronic device; and
b. coupling a removable lid to the support bracket structure, wherein the removable lid is configured to provide selective access to the electronic device.

42. The method according to claim 41 further comprising the step of coupling a heat exchanger to the electronic device, wherein the heat exchanger is positioned between the electronic device and the removable lid.

43. The method according to claim 41 further comprising the step of coupling a spring urged clip to the support bracket structure, wherein the spring urged clip applies a consistent force upon the removable lid.

44. The method according to claim 41 wherein the removable lid is coupled to the support bracket structure by a snap fit.

45. The method according to claim 41 wherein the removable lid is circular.

46. The method according to claim 46 wherein the removable lid is coupled to the support bracket structure by rotating the removable lid in a predetermined direction.

47. The method according to claim 41 wherein the removable lid is rectangular.

48. The method according to claim 41 wherein the removable lid is coupled to the support bracket structure by sliding a protrusion extending from the removable lid into a receiving slot in the support bracket structure.

49. The method according to claim 41 wherein the removable lid is coupled to the support bracket structure by sliding a protrusion extending from the support bracket structure into a receiving slot in the removable lid.

50. The method according to claim 41 wherein the removable lid includes a plurality of resilient fingers configured to snap into a receiving slot in the support bracket structure.

51. The method according to claim 41 wherein the removable lid is made of a material for to achieve desired heat spreading of heat generated from within the heat exchanger.

52. The method according to claim 51 wherein the material is copper.

53. The method according to claim 41 wherein the support bracket and the removable lid are configured to maintain a substantially constant force upon the heat source.

54. The method according to claim 5 3 wherein the support bracket structure is further configured to transfer the substantially constant force over a relatively large surface area on the circuit board thereby protecting the electronic device from bending, breaking or collapsing from the substantially constant force.

55. The method according to claim 41 wherein the support bracket structure is configured to prevent undesired movement of the circuit board.

56. The method according to claim 41 wherein the removable lid is configured to apply a consistent force upon the electronic device.

57. The method according to claim 41 wherein the support bracket further comprises:
a. a first portion configured to secure a portion of the removable lid; and
b. a second portion configured to exert only a vertical force to the removable lid when coupled to the first portion.
